(19) United States
(12) Patent Application Publication
(10) Pub. No.: US 2007/0001284 A1
(43) Pub. Date: Jan. 4, 2007

(54) Semiconductor package having lead free conductive bumps and method of manufacturing the same

(75) Inventors: Bo-Seong Kim, Seoul (KR); Sang-Ho An, Suwon-si (KR); In-Ku Kang, Gheonan-si (KR); Pyoung-Wan Kim, Cheonan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/476,835

(22) Filed: Jun. 29, 2006

Related U.S. Application Data
(60) Provisional application No. 60/712,430, filed on Aug. 31, 2005.

(30) Foreign Application Priority Data
Jun. 29, 2005 (KR) 2005-57072

(51) Int. Cl. H01L 23/04

(52) U.S. Cl. 257/698

(57) ABSTRACT

A semiconductor package may include a printed circuit board having a conductive bump pad. At least one semiconductor chip may be electrically connected to the printed circuit board. A lead free conductive bump may be mounted on the conductive bump pad. The lead free conductive bump may include no more than about 0.3% by weight of copper. The lead free conductive bump may include about 3.0% to about 4.0% by weight of silver, about 0.1% to about 0.3% by weight of copper and about 95.7% to about 96.9% by weight of tin.

### CROSS REFERENCE TO RELATED APPLICATION

This US non-provisional application claims benefit of priority under 35 USC §119 to U.S. Provisional Application No. 60/712,430 filed Aug. 31, 2005, the contents of which are herein incorporated by reference in its entirety.

### PRIORITY STATEMENT

This application claims benefit of priority under 35 USC §119 to Korean Patent Application No. 2005-57072, filed on Jun. 29, 2005, the contents of which are herein incorporated by reference in its entirety.

### BACKGROUND

1. Field of the Invention

Example, non-limiting embodiments of the present invention relate to a semiconductor package and a method of manufacturing the semiconductor package. More particularly, example embodiments of the present invention relate to a semiconductor package that may provide improved impact characteristic in relation to solder joint reliability (SJR), and a method of manufacturing the semiconductor package.

2. Description of the Related Art

A ball grid array (BGA) package may have conductive bumps serving as external connection terminals. The conductive bumps may not include lead, which may be environmentally hazardous. As a result, a lead free conductive bump including Sn—Ag—Cu may be used as the external connection terminal of the semiconductor package.

Although conventional lead free conductive bumps are generally thought to provide acceptable performance, they are not without shortcomings. For example, the lead free conductive bump may have a deteriorated impact characteristic. The deteriorated impact characteristic may become more problematic in a semiconductor package employed in an electronic device such as a mobile phone (for example) sensitive to an impact.

FIG. 1 is a cross sectional view of a conventional stacked semiconductor package.

Referring to FIG. 1, a conventional stacked semiconductor package 100 (e.g., a multi chip package (MCP)) may include a printed circuit board 2 that may support a stack of semiconductor chips 1. The semiconductor chips 1 may be electrically connected to the printed circuit board 2 through bonding wires 4. An epoxy mold compound (EMC) 5 may seal a portion of the printed circuit board 2, the semiconductor chip 1 and the bonding wire 4. A conductive bump pad (not shown), which may be provided on the printed circuit board 2, may support a lead free conductive bump 3. The conductive bump pad may be exposed through a photo solder resist (PSR), which may be provided on the printed circuit board 2.

The conductive bump pad may include copper (Cu). A nickel (Ni) plating layer 13 (see FIG. 2) and a gold (Au) plating layer may be provided on the conductive bump pad. When the lead free conductive bump 3 is mounted on the conductive bump pad, an inter-metallic compound layer 11, 12 (see FIG. 2) may be formed at an interface between the lead free conductive bump 3 and the conductive bump pad. A separation and a crack 14 (see FIG. 2) of the lead free conductive bump 3 may be generated in the inter-metallic compound layer 11, 12.

FIG. 2 is a picture from a scanning electron microscope (SEM) of an inter-metallic compound layer 11, 12 of a solder joint after performing a drop impact test with respect to the conventional stacked semiconductor package 100. According to convention, the lead free conductive bump 3 may have about 3.0% by weight of silver (Ag), about 0.5% by weight of copper (Cu) and about 96.5% by weight of tin (Sn).

As shown in FIG. 2, when the drop impact test is carried out on the conventional semiconductor package 100 including the lead free conductive bump 3 (which contains about 0.5% by weight of copper), a crack 14 may be generated in a solder joint of an inter-metallic compound layer. The inter-metallic compound layer may include an Ni₃Sn layer 11 and a (Cu, Ni)₆Sn₅ layer 12.

As described above, the conventional stacked semiconductor package 100 may include the lead free conductive bump 3 containing no less than about 0.5% by weight of copper. As a result, when the drop impact test is performed on the conventional stacked semiconductor package 100, the crack 14 may be generated in the inter-metallic compound layer between the lead free conductive bump 3 and the conductive bump pad so that the lead free conductive bump 3 may become detached from the conductive bump pad. Thus, the conventional stacked semiconductor package 100 may have inferior solder joint reliability.

### SUMMARY

According to an example, non-limiting embodiment, a semiconductor package may include a printed circuit board having a conductive bump pad. At least one semiconductor chip may be electrically connected to the printed circuit board. A lead free conductive bump may be mounted on the conductive bump pad. The lead free conductive bump may include no more than about 0.3% by weight of copper.

According to another example, non-limiting embodiment, a semiconductor package may include a first printed circuit board having a conductive bump pad. At least one semiconductor chip may be electrically connected to the first printed circuit board. A first lead free conductive bump may be mounted on the conductive bump pad. The first lead free conductive bump may include no more than about 0.3% by weight of copper. A second printed circuit board may be electrically connected to the first lead free conductive bump. A second lead free conductive bump may be electrically connected to the second printed circuit board.

According to another example, non-limiting embodiment, a method of manufacturing a semiconductor package may involve forming a conductive bump pad on a first printed circuit board. At least one semiconductor chip may be electrically connected to the first printed circuit board. A first lead free conductive bump may be mounted on the conductive bump pad. The first lead free conductive bump may include no more than about 0.3% by weight of copper. A second printed circuit board may be electrically connected to the first lead free conductive bump. A second lead free conductive bump may be electrically connected to the second printed circuit board.

### BRIEF DESCRIPTION OF THE DRAWINGS

Example, non-limiting embodiments of the invention will become readily apparent by reference to the following detailed description when considered in conjunction with the accompanying drawings.

FIG. 1 is a cross sectional view of a conventional stacked semiconductor package.

FIG. 2 is a scanning electron microscope (SEM) picture of an inter-metallic compound layer of a solder joint after performing a drop impact test with respect to the conventional stacked semiconductor package.

FIG. 3 is a cross sectional view of a stacked semiconductor package in accordance with an example, non-limiting embodiment of the present invention.

FIG. 4 is a cross sectional view of a solder joint of the stacked semiconductor package in FIG. 3.

FIG. 5 is an enlarged cross sectional view of a portion “A” in FIG. 4.

FIG. 6 is an SEM picture of a solder joint of the stacked semiconductor package on which a temperature cycle test is carried out.

FIG. 7 is a graph illustrating results of a drop impact test on the stacked semiconductor package in FIG. 3 and a conventional stacked semiconductor package.

FIG. 8 is a cross sectional view of a lower solder joint of a stacked semiconductor package in accordance with another example, non-limiting embodiment of the present invention.

FIG. 9 is a flow chart of a method that may be implemented to manufacture the stacked semiconductor package in FIG. 3.

### DESCRIPTION OF EXAMPLE, NON-LIMITING EMBODIMENTS

Example, non-limiting embodiments of the present invention will be described with reference to the accompanying drawings. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. The principles and features of this invention may be employed in varied and numerous embodiments without departing from the scope of the invention. In the drawings, the size and relative sizes of layers and regions may be exaggerated for clarity. The drawings are not to scale.

It will be understood that when an element or layer is referred to as being “on”, “connected to” and/or “coupled to” another element or layer, the element or layer may be directly on, connected and/or coupled to the other element or layer or intervening elements or layers may be present In contrast, when an element is referred to as being “directly on,” “directly connected to” and/or “directly coupled to” another element or layer, there may be no intervening elements or layers present Like numbers refer to like elements throughout. As used herein, the term “and/or” may include any and all combinations of one or more of the associated listed items.

Spatially relative terms, such as “beneath”, “below”, “lower”, “above”, “upper” and the like, may be used to describe an element and/or feature's relationship to another element(s) and/or feature(s) as illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (rotated 90 degrees or at other orientations) and the spatially relative descriptors used herein interpreted accordingly.

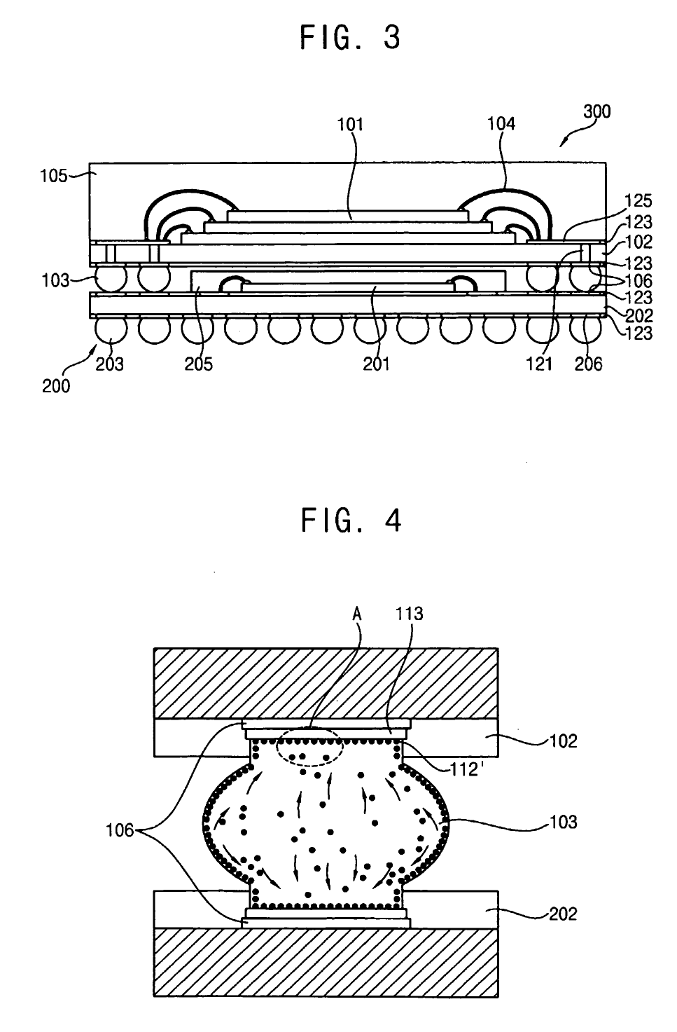

FIG. 3 is a cross sectional view of a stacked semiconductor package in accordance with an example, non-limiting embodiment of the present invention.

Referring to FIG. 3, a multi-stacked semiconductor package (MSP) 300 may include a first printed circuit board 102. At least one semiconductor chip 101 may be electrically connected to the first printed circuit board 102 through a bonding wire 104. By way of example only, the semiconductor chip 102 may be a memory chip and/or a system LSI semiconductor chip.

The first printed circuit board 102 may include a flexible substrate and/or a rigid substrate. The first printed circuit board 102 may be fabricated from polyimide, FR4 resin, and/or FT resin, for example.

An epoxy mold compound (EMC) 105 may seal a portion of the first printed circuit board 102, the semiconductor chip 101 and the bonding wire 104. A lead free conductive bump 103 may be mounted on a conductive bump pad 106 of the first printed circuit board 102. The lead free conductive bump 103 may be electrically connected to the semiconductor chip 101 through the conductive bump pad 106, a via hole 121, a metal line 125 and the bonding wire 104. A photo solder resist (PSR) 123, which may include an insulation material, may isolate the conductive bump pads 106 from each other.

The MSP 300 may implement a lead free conductive bump 103, which may contain Sn—Ag—Cu. The lead free conductive bump 103 may be mounted on the conductive bump pad 106. The MSP 300 may be mounted on a second printed circuit board 202 of another BGA package 200.

By way of example only, the conductive bump 103 of the MCP 300 may be positioned in a peripheral region of the first printed circuit board 102. The conductive bump 103 may have a sufficient height to form a space between a lower face of the MSP 300 and an EMC 205 of the BGA package 200 in which a semiconductor chip 201 may be provided. The conductive bump 103 of the MSP 300 has a greater height than that of a conductive bump 203 of the BGA package 200. By way of example only, the PSR 123 may have an opening having a width of about 0.3 mm, and the conductive bump 103 may have a ball shape with a diameter of about 0.42 mm. Conductive bumps 103 having numerous and varied shapes may be suitably implemented

The second printed circuit board 202 may include a flexible substrate and/or a rigid substrate. The second printed circuit board 202 may be fabricated from polyimide, FR4 resin and/or FT resin, for example.

Example embodiments of the present invention may be employed in a BGA package having a conductive bump as an external connection terminal. For example, example embodiments of the present invention may be employed in a diverse stacked semiconductor package having a conductive bump as an external connection terminal.

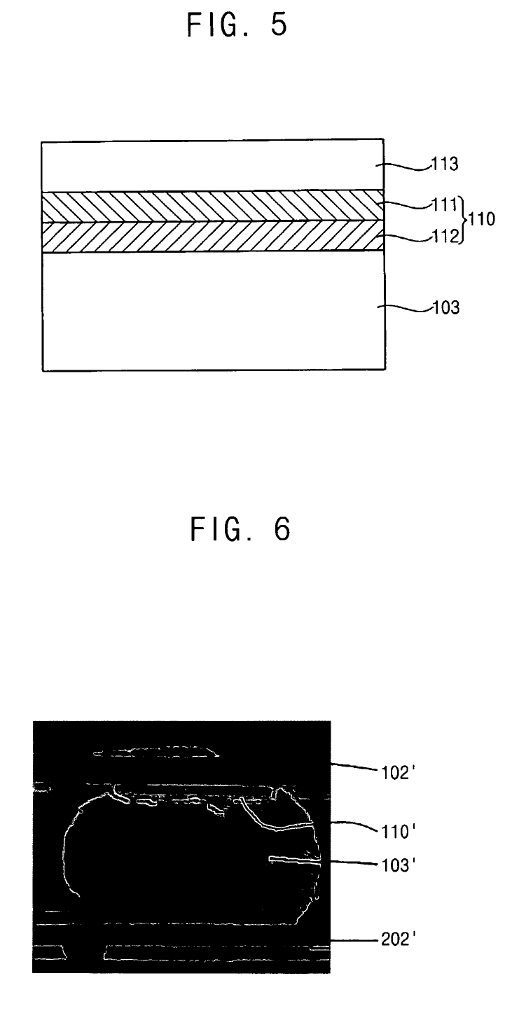

FIG. 4 is a cross sectional of a solder joint of the stacked semiconductor package in FIG. 3, and FIG. 5 is an enlarged cross sectional view of a portion “A” in FIG. 4.

Referring to FIG. 4, the conductive bump 103 of the MSP 300 may include (for example) about 3.0% to about 4.0% by weight of silver, about 0.1% to about 0.3% by weight copper, and about 95.7% to about 96.9% by weight of tin. Further, the conductive bump pad 106 of a solder joint may include (for exanple) about 0.1% to about 0.3% by weight of copper.

An attachment process (e.g., a conventional reflow process) may be implemented to attach the lead free conductive bump 103 to the conduct bump pads 106. During the attachment process, the copper in the conductive bump 103 may diffuse to form a layer 112 including (Cu, Ni)₆Sn₅ on a nickel plating layer 113 that may be provided on the conductive bump pads 106. The copper content of the conductive bump 103 may affect the thickness of the layer 112 that forms during the attachment process. Specifically, a higher content of copper in the conductive bump 103 may result in the layer 112 having an increased thickness, while a lower content of copper in the conductive bump 103may result in the layer 112 having a reduced thickness. To reduce the thickness of the resulting (Cu, Ni)₆Sn₅ layer 112, the conductive bump 103 may have no more than about 0.3% by weight of copper, which is less than about 0.5% by weight of copper that may present in the conventional conductive bump 3 of FIGS. 2 and 3.

Referring to FIG. 5, the conductive bump 103 including Sn—Ag—Cu may be mounted on the conductive pad 106 on which the nickel plating layer 113 and a gold plating layer (not shown) may be formed. For example, a layer of nickel 113 may be provided on the conductive bump pad 106, and a layer of gold (not shown) may be provided on the layer of nickel 113.

The gold plating layer may improve wetting of an interface between the conductive bump pad 106 (which may include copper) and the lead free conductive bump 103 to enhance a bonding strength between the conductive bump pad 106 and the conductive bump 103. The gold plating layer may diffuses into the conductive bump 103 of the solder joint.

During the attachment process, at least two inter-metallic compound layers 110 may be formed between the nickel-plating layer 113 of the conductive bump pad 106 and the conductive bump 103. The two inter-metallic compound layers 110 may include a Ni₃Sn₄ layer 111 and the (Cu, Ni)₆Sn₅ layer 112. The Ni₃Sn₄ layer 111 may be formed on the nickel-plating layer 113. The (Cu, Ni)₆Sn₅ layer 112 may be formed on the conductive bump 103.

The Ni₃Sn₄ layer 111 and the (Cu, Ni)₆Sn₅ layer 112 may have atomic arrangements different from each other, which may reduce the bonding strength between the inter-metallic compound layers 110. The bonding strength of the inter-metallic compound layer 110 may be increased by reducing the thickness of the multi-layer structure 110.

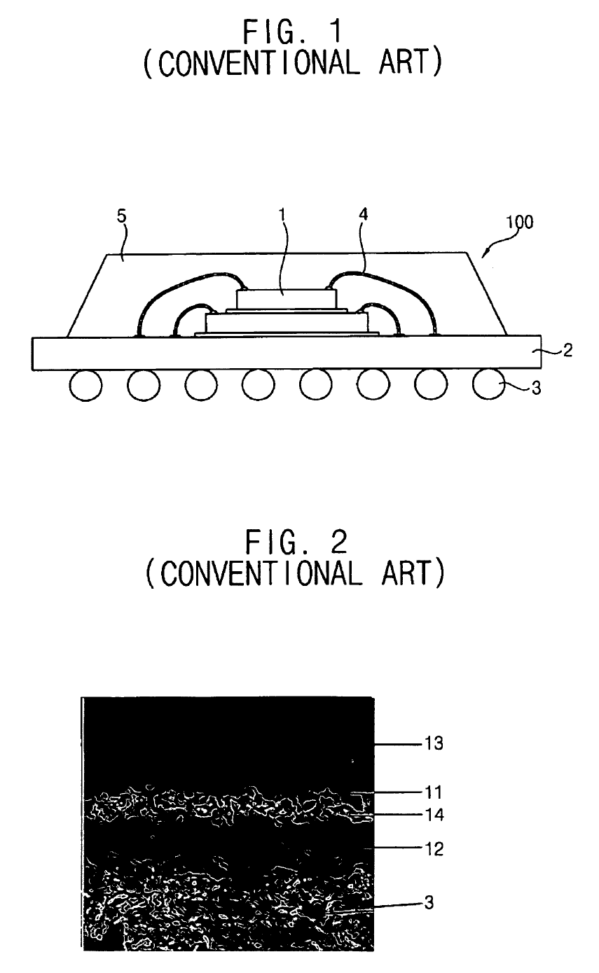

According to example embodiments of the present invention, the conductive bump 103 may have no more than about 0.3% by weight of copper, which is less than about 0.5% by weight of copper that may be present in the conventional conductive bump 3 of FIGS. 1 and 2. Accordingly, as compared to conventional devices, the thickness of the inter-metallic compound layer including the (Cu, Ni)₆Sn₅ layer 112 may be reduces so that the SJR may be improved.

Example embodiments of the prevent invention may be employed in a stacked semiconductor package having a conductive bumps that may have a greater height than that of a conventional lead free conductive bump. When a conductive bump includes about 3.0% to about 4.0% by weight of silver, the conductive bump may have a melting point of about 220° C. to about 250° C.

FIG. 6 is an SEM picture of a solder joint of the stacked semiconductor package in FIG. 3 on which a temp cycle test may be carried out.

Referring to FIG. 6, a temperature cycle test may be performed on a stacked semiconductor package in which a first printed circuit board 102′ may be electrically connected to a second printed circuit board 202′ by a conductive bump 103′. Here, the conductive bump 103′ may include less than about 0.1% by weight of copper. The temperature cycle test may be carried out at a temperature of about −25° C. to about −125° C. for a time of about 30 min/cycle. As shown in FIG. 6, an inter-metallic compound layer 110′ at an interface between the conductive bump 103′ and the conductive bump pad may be cracked.

When the conductive bump 103 includes about 0.1% to about 0.3% by weight of copper, according to example embodiments of the present invention, the cracking of the inter-metallic compound layer 110 between the conductive bump 103 and the conductive bump pad 106 may be reduced.

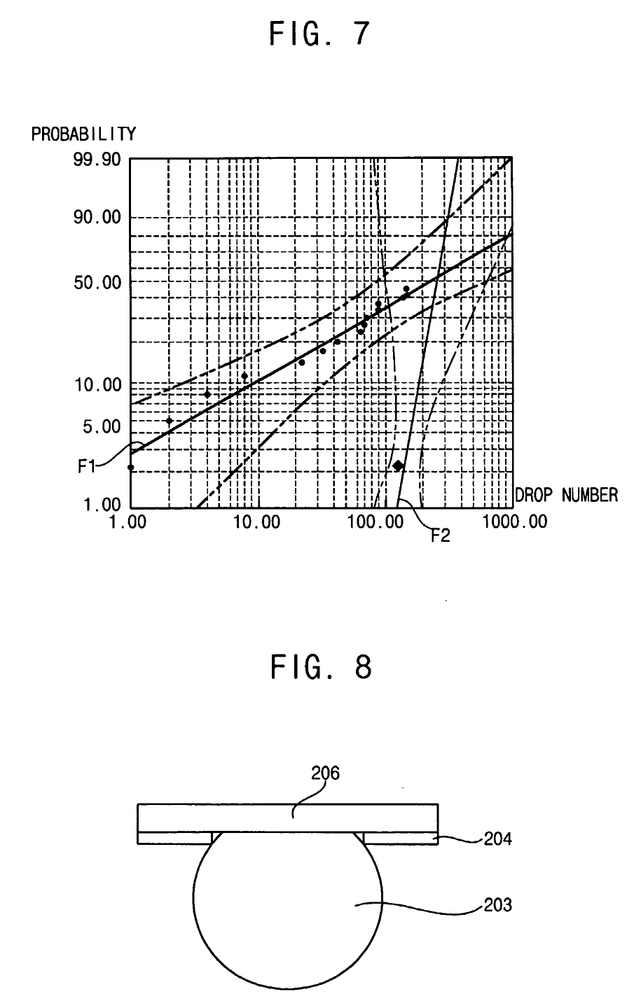

FIG. 7 is a graph illustrating results of a drop impact test on the stacked semiconductor package in FIG. 3, and a conventional stacked semiconductor package.

When an impact is repeatedly applied to the stacked semiconductor package 300, the inter-metallic compound layer 110 between the conductive bump 103 and the conductive bump pad 106 may eventually crack. The inter-metallic compound layer 110 may be harder and more fragile than the conductive bump 103. The relatively softer conductive bump 103 may have an impact-absorbing ability relatively higher than that of the inter-metallic compound layer 110.

In the drop impact test, a force may be applied from the inter-metallic compound layer 110 into the conductive bump 103.

A drop impact test may be carried out as follows. A sample may include a semiconductor package mounted on a printed circuit board. The sample may be loaded into equipment for performing the drop impact test. The sample may be dropped toward a rigid base. The impact force applied to the sample from the rigid base may be measured.

In the drop impact test in FIG. 7, four semiconductor packages were mounted on each of fifteen printed circuit board (PCB) modules. The PCB modules were facedown dropped toward a rigid base to apply an impact of about 1,500 g/milliseconds (g is an acceleration of gravity) to the PCB modules. The PCB modules were repeatedly dropped until a first failure (corresponding to a crack in the inter-metallic compound layer between the conductive bump and the conductive bump pad in the semiconductor package of the PCB module)was generated. The PCB modules were dropped 200 to 250 times. Drop numbers of the PCB modules at which the first failure was generated are shown as a normal distribution curve (in phantom) in FIG. 7. That is, the drop numbers of the PCB modules until the first failure was generated in the semiconductor package are represented as the normal distribution curve (shown in phantom). A probability of the normal distribution curve average is shown as the Y-axis (i.e., the vertical axis) of FIG. 7.

Referring to FIG. 7, the X-axis (or horizontal axis) represents the drop number and the Y-axis indicates the average probability of the sample failing. That is, the Y-axis represents the probability of the normal distribution curve average such as 5%, 10%, etc., which indicates the drop numbers of the sample that is repeatedly dropped until the first failure is generated in the sample.

In FIG. 7, a line F1 connected between ● indicates a result of the drop impact test that is performed on a semiconductor package including a conventional lead free conductive bump having 3.0% by weight of silver, 0.5% by weight of copper and 96.5% by weight of tin. A line F2 connected between ♦ indicates a result of the drop impact test that is performed on a semiconductor package including a lead free conductive bump having 3.0% by weight of silver, 0.2% by weight of copper and 96.8% by weight of tin. As shown in FIG. 7, in the line F1, the drop number corresponding to a probability of 5% is 2. In the line F2, all of the drop numbers are 180.

That is, when the drop impact test is performed on a semiconductor package including a lead free conductive bump having 3.0% by weight of silver, 0.2% by weight of copper and 96.8% by weight of tin, the drop numbers determined to be failed are increased. In FIG. 7, when the drop impact test was performed on a semiconductor package including a lead free conductive bump having 3.0% by weight of silver, 0.5% by weight of copper and 96.5% by weight of tin, a semiconductor package fail from a first drop. On the contrary, when the drop impact test is performed on a semiconductor package including a lead free conductive bump having 3.0% by weight of silver, 0.2% by weight of copper and 96.8% by weight of tin in accordance with example embodiments of the present invention, the semiconductor package only failed from one hundred fiftieth drop.

FIG. 8 is a cross sectional view of a lower solder joint of a stacked semiconductor package in accordance with another example, non-limiting embodiment of the present invention.

Referring to FIG. 8, a conductive bump pad 206, which may include copper, may be exposed to the air. Due to such exposure, the copper in the conductive bump pad 206 may react with oxygen in the air to form a compound including copper and oxygen on the conductive bump pad 206; i.e., the surface of the conductive bump pad 206 may become oxidized. The compound including copper and oxygen may reduce a bonding strength of a conductive bump 203, which may be mounted on an opened region of a PSR 204. An organic solderability preservative (OSP), which may include a soluble oxidation-preventing material, may be coated on a surface of the conductive bump pad 206 to prevent the surface of the conductive bump pad 206 from being oxidized.

Before the OSP is coated on the surface of the conductive bump pad 206, a cleaning process and/or an etching process (which may remove undesired materials from the conductive bump pad 206) may be carried out to remove a surface portion of the conductive bump pad 206. By way of example only, the removed thickness of the conductive bump pad 206 may be about 5% to about 30% of a total thickness of the conductive bump pad 206.

The conductive bump 203 may be mounted on a mobile type motherboard in an infrared oven by a reflow process, for example. The semiconductor package using the lead free conductive bump that includes no more than about 0.3% by weight of copper may be employed in a printed circuit board on which the semiconductor package may be mounted.

When the OSP is coated on the conductive bump pad 206, a flux such as an organic solvent (for example) may be coated on the surface of the conductive bump pad 206. The reflow process may be carried out on the semiconductor package in the infrared oven. The semiconductor package may be cleaned to remove the OSP from the conductive bump pad 206. The conductive bump 203 may be mounted on the conductive bump pad 206.

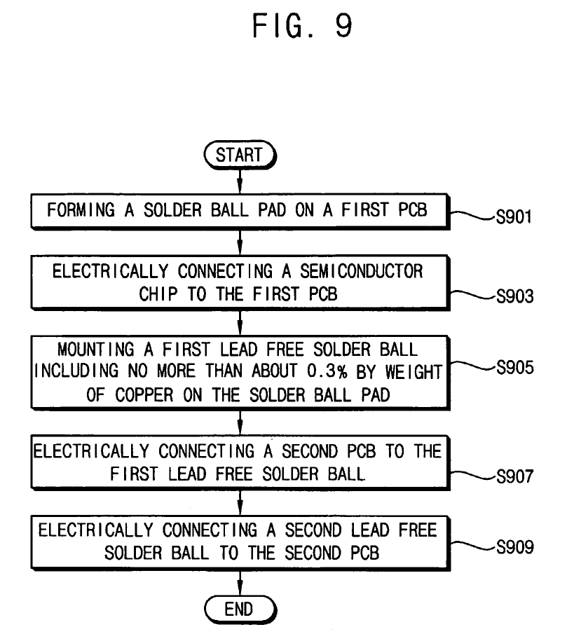

FIG. 9 is a flow chart of a method that may be implemented to manufacture the stacked semiconductor package in FIG. 3.

Referring to FIGS. 3 and 9, in step S901, the conductive bump pad 106 may be formed on the first printed circuit board 102.

In step S903, at least one semiconductor chip may be electrically connected to the first printed circuit board 102 having the conductive bump pad 106 using the bonding wire 104. It will be appreciated that a plurality of semiconductor chips may be vertically stacked on the first printed circuit board 102.

In step S905, the first lead free conductive bump 103 including no more than about 0.3% by weight of copper may be mounted on the conductive bump pad 106. The conductive bump 103 may be electrically connected to the semiconductor chip through the conductive bump pad 106, the via hole 121, the metal line 125 and the bonding wire 104.

In step S907, the fist lead free conductive bump 103 may be electrically connected to the second printed circuit board 202 having the conductive bump pad 206 through the conductive bump pad 106.

In step S909, the second lead free conductive bump 203 may be electrically connected to the second printed circuit board 202 having the conductive bump pad 206.

According to example embodiments of the present invention, the semiconductor packages may have an improved impact characteristics by adjusting a content ratio of copper in the lead free conductive bump and a content ratio of copper in the solder joint. For example, the stacked semiconductor package mounted on a motherboard of an electronic device such as a mobile phone may have a considerably improved impact characteristics.

Having described example, non-limiting embodiments of the present invention, numerous modifications and variations may become apparent to those skilled in the art. It is to be understood that changes may be made to the disclosed embodiment of the present invention, and that such changes may fall within the scope and the spirit of the invention defined by the appended claims.

What is claimed is:

1. A semiconductor package comprising:
a printed circuit board having a conductive bump pad;
at least one semiconductor chip electrically connected to the printed circuit board; and
a lead free conductive bump mounted on the conductive bump pad, the lead free conductive bump including no more than about 0.3% by weight of copper.

2. The semiconductor package of claim 1, wherein the lead free conductive bump comprises about 3.0% to about 4.0% by weight of silver, about 0.1% to about 0.3% by weight of copper and about 95.7% to about 96.9% by weight of tin.

3. The semiconductor package of claim 1, wherein the lead free conductive bump comprises about 3.0% to about 4.0% by weight of silver, about 0.2% by weight of copper and about 95.8% to about 96.8% by weight of tin.

4. The semiconductor package of claim 1, wherein the conductive bump pad comprises no more than about 0.3% by weight of copper.

5. The semiconductor package of claim 1 mounted on a motherboard for a mobile phone.

6. The semiconductor package of claim 1, wherein the semiconductor chip comprises a plurality of semiconductor chips vertically stacked on the printed circuit board.

7. A semiconductor package comprising:
a first printed circuit board having a conductive bump pad;
at least one semiconductor chip electrically connected to the first printed circuit board;
a first lead free conductive bump mounted on the conductive bump pad, the first lead free conductive bump including no more than about 0.3% by weight of copper;
a second printed circuit board electrically connected to the first lead free conductive bump; and
a second lead free conductive bump electrically connected to the second printed circuit board.

8. The semiconductor package of claim 7, wherein the first lead free conductive bump comprises about 3.0% to about 4.0% by weight of silver, about 0.1% to about 0.3% by weight of copper and about 95.7% to about 96.9% by weight of tin.

9. The semiconductor package of claim 7, wherein the first lead free conductive bump comprises about 3.0% to about 4.0% by weight of silver, about 0.2% by weight of copper and about 95.8% to about 96.8% by weight of tin.

10. The semiconductor package of claim 7, wherein the solder ball pad comprises no more than about 0.3% by weight of copper.

11. The semiconductor package of claim 7, wherein the first lead free conductive bump has a size larger than that of the second lead free conductive bump.

12. The semiconductor package of claim 7, wherein a nickel plating layer is formed on a surface of the conductive bump pad.

13. The semiconductor package of claim 7, wherein the second lead flee conductive bump comprises no more than about 0.3% by weight of copper.

14. The semiconductor package of claim 7, wherein the second printed circuit board comprises an organic solderability preservative (OSP) coated on a copper conductive bump pad.

15. The semiconductor package of claim 7, wherein the semiconductor chip comprises a plurality of semiconductor chips vertically stacked on the printed circuit board.

16. The semiconductor package of claim 7 mounted on a motherboard for a mobile phone.

17. A method of manufacturing a semiconductor package, comprising:
forming a conductive bump pad on a first printed circuit board;
electrically connecting at least one semiconductor chip to the first printed circuit board;
mounting a first lead free conductive bump on the conductive bump pad, the first lead free conductive bump including no more than about 0.3% by weight of copper;
electrically connecting a second printed circuit board to the first lead free conductive bump; and
electrically connecting a second lead free conductive bump to the second printed circuit board.

18. The method of claim 17, wherein the first lead free conductive bump comprises about 3.0% to about 4.0% by weight of silver, about 0.1% to about 0.3% by weight of copper and about 95.7% to about 96.9% by weight of tin.

19. The method of claim 17, wherein the conductive bump pad comprises no more than about 0.3% by weight of copper.

20. The method of claim 17, wherein the first lead free conductive bump has a size larger than that of the second lead free conductive bump.

21. The method of claim 17, wherein the second lead free conductive bump comprises no more than about 0.3% by weight of copper.

22. The method of claim 17, wherein the semiconductor chip comprises a plurality of semiconductor chips vertically stacked on the printed circuit board.
